(19) United States
(12) Patent Application Publication
(10) Pub. No.: US 2024/0006552 A1
(43) Pub. Date: Jan. 4, 2024

(54) LIGHT-EMITTING DEVICE AND MANUFACTURING METHOD THEREFOR

(71) Applicant: ENKRIS SEMICONDUCTOR, INC., Suzhou, Jiangsu (CN)

(72) Inventor: KAI CHENG, Suzhou, Jiangsu (CN)

(73) Assignee: ENKRIS SEMICONDUCTOR, INC., Suzhou, Jiangsu (CN)

(21) Appl. No.: 18/251,365

(22) PCT Filed: Nov. 18, 2020
(86) PCT No.: PCT/CN2020/129776

§ 371 Date: May 1, 2023

(51) Int. Cl. H01L 33/00; H01L 33/10

(52) U.S. Cl. CPC H01L 33/0093; H01L 33/105

(57) ABSTRACT

A light-emitting device and a method for manufacturing the same are provided. The method includes: providing an epitaxial base with a first concave portion, wherein an inner surface of the first concave portion is a curved surface; epitaxially growing a light-emitting structure layer on the epitaxial base, wherein the light-emitting structure layer comprises a first surface and a second surface opposite the first surface, and the second surface protrudes towards the first concave portion; forming a first reflector layer on the first surface; and removing the epitaxial base to form a second reflector layer covering the second surface. A curved resonant cavity can be formed by the method.

### CROSS REFERENCE TO RELATED APPLICATIONS

This application is a National Stage of International Application No. PCT/CN2020/129776, filed on Nov. 18, 2020, the contents of all of which are incorporated herein by reference in their entirety.

### TECHNICAL FIELD

The present disclosure relates to the field of semiconductor technologies, and in particular to a light-emitting device and a method for manufacturing the same.

### BACKGROUND

In recent years, semiconductor light-emitting devices, as a new generation of green light sources, are widely used in lighting, backlighting, display, indication and other fields.

In order to improve the performance of the semiconductor light-emitting device, a resonant cavity is often formed in the semiconductor light-emitting device. The basic structure of the semiconductor light-emitting device with the resonant cavity includes a first reflector layer, a second reflector layer, a light-emitting structure layer, and so on. The light-emitting structure layer is disposed between the first reflector layer and the second reflector layer. However, the technician is unable to form a curved resonant cavity in the actual product.

### SUMMARY

The present disclosure aims to provide a light-emitting device and a method for manufacturing the same, and a curved resonant cavity can be formed in the light-emitting device.

According to an aspect of the present disclosure, a method for manufacturing a light-emitting device is provided, and the method includes:

providing an epitaxial base with a first concave portion, where an inner surface of the first concave portion is a curved surface;

epitaxially growing a light-emitting structure layer on the epitaxial base, where the light-emitting structure layer includes a first surface and a second surface opposite the first surface, and the second surface protrudes towards the first concave portion;

forming a first reflector layer on the first surface; and

removing the epitaxial base to form a second reflector layer covering the second surface.

Furthermore, the epitaxial base includes a substrate, and the first concave portion is formed in the substrate.

Furthermore, the epitaxial base includes a substrate and a nucleation layer from bottom to top, the first concave portion is formed in the substrate, and the nucleation layer is formed on the substrate in a same shape with the first concave portion.

Furthermore, the epitaxial base includes a substrate, a dielectric layer, and a nucleation layer from bottom to top, the first concave portion is formed in the dielectric layer, and the nucleation layer is formed on the dielectric layer in a same shape with the first concave portion.

Furthermore, the first concave portion is plural in number.

Furthermore, the light-emitting structure layer further includes a side wall connecting the first surface and the second surface, and forming the second reflector layer covering the second surface includes:

forming the second reflector layer covering the side wall of the light-emitting structure layer and the second surface.

Furthermore, the second reflector layer has a reflectivity of 50%-80%.

Furthermore, the second reflector layer is made of insulating material.

Furthermore, the light-emitting structure layer further includes an active layer, which includes a first conductive type semiconductor layer, a light-emitting layer, and a second conductive type semiconductor layer from top to bottom, and the method further includes:

forming a first electrode electrically connected to the first conductive type semiconductor layer; and

forming a second electrode electrically connected to the second conductive type semiconductor layer.

Furthermore, the first electrode and the second electrode are respectively disposed on both sides of the light-emitting structure layer.

Furthermore, both the first electrode and the second electrode are disposed on a side of the first conductive type semiconductor layer away from the first reflector layer.

Furthermore, the light-emitting structure layer includes an active layer and an oxide layer stacked, and the oxide layer includes a low resistance region and a high resistance region surrounding the low resistance region, and the resistance of the low resistance region is lower than that of the high resistance region.

According to an aspect of the present disclosure, a light-emitting device is provided, and the light-emitting device is manufactured by the above-mentioned method.

### BRIEF DESCRIPTION OF THE DRAWINGS

FIG. 1 is a flowchart illustrating a method for manufacturing a light-emitting device according to an embodiment 1 of the present disclosure.

FIG. 2 is a schematic diagram illustrating an epitaxial base in the embodiment 1 of the present disclosure.

FIG. 3 is a schematic diagram illustrating a structure obtained after forming a support layer in the embodiment 1 of the present disclosure.

FIG. 4 is a schematic diagram illustrating a structure obtained after patterning a light-emitting structure layer in the embodiment 1 of the present disclosure.

FIG. 5 is another schematic diagram illustrating a structure obtained after patterning the light-emitting structure layer in the embodiment 1 of the present disclosure.

FIG. 6 is a schematic diagram illustrating a light-emitting device according to the embodiment 1 of the present disclosure.

FIG. 7 is a schematic diagram illustrating an epitaxial base according to an embodiment 2 of the present disclosure.

FIG. 8 is a schematic diagram illustrating an epitaxial base according to an embodiment 3 of the present disclosure.

FIG. 9 is a schematic diagram illustrating a light-emitting device according to an embodiment 4 of the present disclosure.

FIG. 10 is a schematic diagram illustrating a light-emitting device according to an embodiment 5 of the present disclosure.

FIG. 11 is a schematic diagram illustrating a light-emitting device according to an embodiment 6 of the present disclosure.

FIG. 12 is a schematic diagram illustrating a light-emitting device according to an embodiment 7 of the present disclosure.

FIG. 13 is another schematic diagram illustrating the light-emitting device in the embodiment 7 of the present disclosure.

List of Reference Numerals: epitaxial base 1; first concave portion 101; substrate 102; nucleation layer 103; dielectric layer 104; light-emitting structure layer 2; active layer 20; first conductive type semiconductor layer 201; light-emitting layer 202; second conductive type semiconductor layer 203; first surface 204; second surface 205; oxide layer 21; low resistance region 211; high resistance region 212; first reflector layer 3; ITO layer 4; support layer 5; heavily doped silicon substrate 501; metal bonding layer 502; metal protection layer 6; isolation trench 7; second reflector layer 8; first electrode 9; second electrode 10.

### DETAILED DESCRIPTION OF THE EMBODIMENTS

Exemplary embodiments will be described in detail herein, examples of which are represented in the drawings. Where the following description relates to the accompanying drawings, the same numerals in the different drawings indicate the same or similar elements unless otherwise indicated. The embodiments described in the following exemplary embodiments do not represent all embodiments that are consistent with the present disclosure. Rather, they are only examples of devices that are consistent with some aspects of the present disclosure, as detailed in the appended claims.

### Embodiment 1

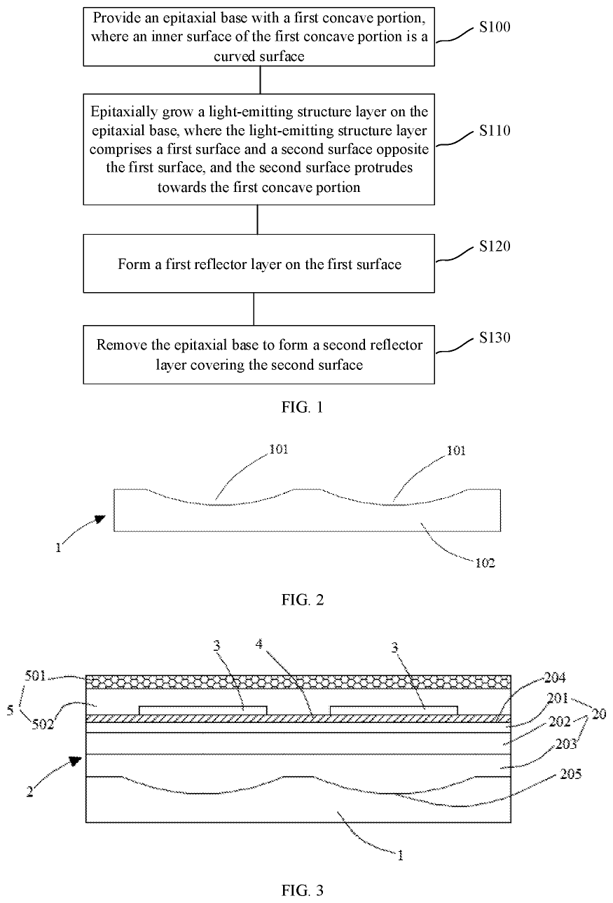

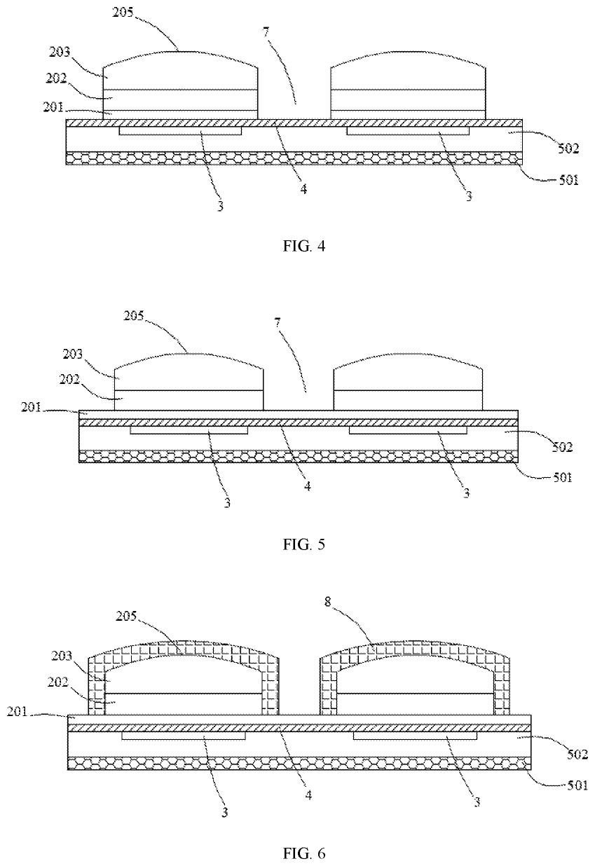

FIG. 1 is a flowchart illustrating a method for manufacturing a light-emitting device according to an embodiment 1 of the present disclosure. FIG. 2 is a schematic diagram illustrating an epitaxial base in the embodiment 1 of the present disclosure. FIG. 3 is a schematic diagram illustrating a structure obtained after forming a support layer in the embodiment 1 of the present disclosure. FIG. 4 is a schematic diagram illustrating a structure obtained after patterning a light-emitting structure layer in the embodiment 1 of the present disclosure. FIG. 5 is another schematic diagram illustrating a structure obtained after patterning the light-emitting structure layer in the embodiment 1 of the present disclosure. FIG. 6 is a schematic diagram illustrating a light-emitting device according to the embodiment 1 of the present disclosure.

As shown in FIG. 1, the method for manufacturing the light-emitting device according to the embodiment 1 of the present disclosure may include steps S100 to S130.

At step S100, an epitaxial base with a first concave portion is provided, where an inner surface of the first concave portion is a curved surface.

At step S110, a light-emitting structure layer is epitaxially grown on the epitaxial base, where the light-emitting structure layer includes a first surface and a second surface opposite the first surface, and the second surface protrudes towards the first concave portion.

At step S120, a first reflector layer is formed on the first surface.

At step S130, the epitaxial base is removed to form a second reflector layer covering the second surface.

According to the method for manufacturing the light-emitting device in the embodiment 1 of the present disclosure, the epitaxial base has the first concave portion, and the inner surface of the first concave portion is a curved surface, such that the second surface of the light-emitting structure layer grown on the epitaxial base protrudes towards the first concave portion. As a result, the second reflector layer covering the second surface protrudes outward to form a curved resonant cavity, such that the volume of the resonant cavity is increased, light confinement is enhanced, and the optoelectronic performance of the light-emitting device is improved.

The steps of the method for manufacturing the light-emitting device in the embodiment 1 of the present disclosure are described in detail below.

In step S100, an epitaxial base with a first concave portion is provided, where an inner surface of the first concave portion is a curved surface.

As shown in FIG. 2, this first concave portion 101 may be flared, that is, the area of the section of the first concave portion 101 in a direction parallel to the epitaxial base 1 gradually becomes larger from the bottom to the top of the first concave portion 101. The number of the first concave portions 101 may be one, two, three or more. For example, the first concave portion 101 is plural in number.

The plurality of first concave portions may be disposed on the same surface of the epitaxial base 1, and the plurality of first concave portions 101 are spaced apart. In this embodiment, the epitaxial base 1 may include a substrate 102, and the first concave portion 101 may be formed in the substrate 102. The substrate 102 may be a silicon substrate, or a silicon carbide substrate, but is not limited thereto, and may also be a sapphire substrate.

In step S110, the light-emitting structure layer is epitaxially grown on the epitaxial base, where the light-emitting structure layer includes the first surface and the second surface opposite the first surface, and the second surface protrudes towards the first concave portion.

As shown in FIG. 3, the light-emitting structure layer 2 may be grown on a side of the substrate 102 with the first concave portion. The light-emitting structure layer 2 includes an active layer 20. The active layer 20 may include a first conductive type semiconductor layer 201, a light-emitting layer 202, and a second conductive type semiconductor layer 203 from top to bottom. For example, epitaxially growing the light-emitting structure layer 2 on the epitaxial base 1 may include: epitaxially growing the second conductive type semiconductor layer 203, the light-emitting layer 202, and the first conductive type semiconductor layer 201 on the epitaxial base 1 in turn. The light-emitting layer 202 can be at least one of a single quantum well structure, a multiple quantum well (MQW) structure, a quantum line structure, or a quantum dot structure. As an example, the light-emitting layer 202 is a multiple quantum well structure, and the light-emitting layer 202 includes alternately provided potential well layers and potential barrier layers. The first conductive type is different from the second conductive type. The first conductive type semiconductor layer 201 may be a P-type semiconductor layer, the second conductive type semiconductor layer 203 may be a N-type semiconductor layer, but the present disclosure is not specifically limited. The first surface 204 of the light-emitting structure layer 2 can be a surface of the first conductive type semiconductor layer 201 facing away from the light-emitting layer 202. The second surface 205 of the light-emitting structure layer 2 may be a surface of the second conductive type semiconductor layer 203 facing away from the light-emitting layer 202, and the second surface 205 closely contacts the inner surface of the first concave portion 101. Since the inner surface of the first concave portion 101 is curved, such that the second surface 205 protrudes towards the first concave portion 101, that is, the part of the second surface 205 that closely contacts the first concave portion 101 is also a curved surface. In addition, the light-emitting structure layer 2 may also include a side wall connecting the first surface 204 and the second surface 205.

As shown in FIG. 3, the material of the potential well layer, the material of the potential barrier layer, the material of the first conductive type semiconductor layer 201, and the material of the second conductive type semiconductor layer 203 may all be III-V semiconductor materials, but this is not specifically limited by the embodiments of the present disclosure. For example, the material of the potential well layer is InGaN, the material of the potential barrier layer is GaN, the material of the first conductive type semiconductor layer 201 is GaN, and the material of the second conductive type semiconductor layer 203 is GaN.

In step S120, the first reflector layer is formed on the first surface. As shown in FIG. 3, this first reflector layer 3 may be formed on a region of the first surface 204 corresponding to the first concave portion 101. Specifically, the first reflector layer 3 may be formed on the region of the first conductive type semiconductor layer 201 corresponding to the first concave portion 101. The boundary of the opening of the first concave portion 101 may surround the first reflector layer 3, that is, the area of the first reflector layer 3 is smaller than the area of the opening of the first concave portion 101. The first reflector layer 3 may be manufactured by evaporative coating, or by sputtering coating, but the present disclosure is not limited thereto. The reflectivity of the first reflector layer 3 can be 99%-100%, but the present disclosure is not limited thereto. The number of the first reflector layer 3 may be one, two, four or more. For example, both the first concave portion 101 and the first reflector layer 3 are plural in number, and the plurality of first reflector layers 3 corresponds to the plurality of first concave portions 101 one by one.

As shown in FIG. 3, this first reflector layer 3 is a distributed Bragg reflector (DBR). The distributed Bragg reflector is made of a multi-periodic material selected from a group of materials including TiO₂/SiO₂, Ti₃O₅/SiO₂, Ta₂O₅/SiO₂, Ti₃O₅/Al₂O₃, ZrO₂/SiOO₂, or TiO₂/Al₂O₃, but the present disclosure is not limited thereto. Further, as an example, the first reflector layer 3 is a distributed Bragg reflector, before the first reflector layer 3 is formed, this embodiment may also include: forming an indium tin oxide (ITO) layer 4 on the first surface 204. The first reflector layer 3 may be formed on the ITO layer 4. The ITO layer 4 is an indium tin oxide layer.

In step S130, the epitaxial base is removed to form the second reflector layer covering the second surface.

As shown in FIG. 3, before removing the epitaxial base 1, embodiments of the present disclosure may further include: forming a support layer 5 wrapping the first reflector layer 3. Specifically, the support layer 5 is in contact with the ITO layer 4, and the first reflector layer 3 is enclosed between the support layer 5 and the ITO layer 4. The support layer 5 can include a heavily doped silicon substrate 501 and a metal bonding layer 502. The epitaxial base 1 can be removed by a laser peeling process.

As shown in FIGS. 4 and 5, for example, the first reflector layer 3 is plural in number, for example, after removing the epitaxial base 1 and before forming the second reflector layer 8, embodiments of the present disclosure may include: patterning the light-emitting structure layer 2 to form an isolation trench 7. The light-emitting structure layer 2 is divided into multiple portions by the isolation trench 7, each portion of the light-emitting structure layer 2 is provided with a first reflector layer 3, and a depth of the isolation trench 7 can be less than or equal to a thickness of the light-emitting structure layer 2. As shown in FIG. 4, when the depth of the isolation trench 7 is equal to the thickness of the light-emitting structure layer 2, the ITO layer 4 is exposed through the isolation trench 7. As shown in FIG. 5, when the depth of the isolation trench 7 is less than the thickness of the light-emitting structure layer 2, the first conductive type semiconductor layer is exposed through the isolation trench 7. As shown in FIG. 6, the second reflector layer 8 may cover the second surface 205 of the light-emitting structure layer 2. Further, when the second reflector layer 8 covers the second surface 205 of the light-emitting structure layer 2, the second reflector layer 8 may also cover the side wall of the light-emitting structure layer 2. The second reflector layer 8 can cover the entire side wall of the light-emitting structure layer 2, or the second reflector layer 8 can also cover a part of the side wall of the light-emitting structure layer 2, and the present disclosure is not specifically limited thereto. The second reflector layer 8 can be a distributed Bragg reflector. The reflectivity of the second reflector layer 8 may be greater than the reflectivity of the first reflector layer 3, or may also be less than the reflectivity of the first reflector layer 3. For example, the reflectivity of the second reflector layer 8 can be 50% to 80%. In addition, the second reflector layer 8 can be made of insulating material, for example, the second reflector layer 8 covers the side wall of the light-emitting structure layer 2, and the insulating second reflector layer 8 can be served as a light-emitting diode protection layer to protect the top and side walls of the light-emitting diode, so that the step of manufacturing the insulating protection layer is reduced and the cost is saved.

The embodiment 1 of the present disclosure also provides a light-emitting device. The light-emitting device is manufactured by the above-mentioned method, therefore, the light-emitting device has the same beneficial effect, and the present disclosure will not be repeated here.

### Embodiment 2

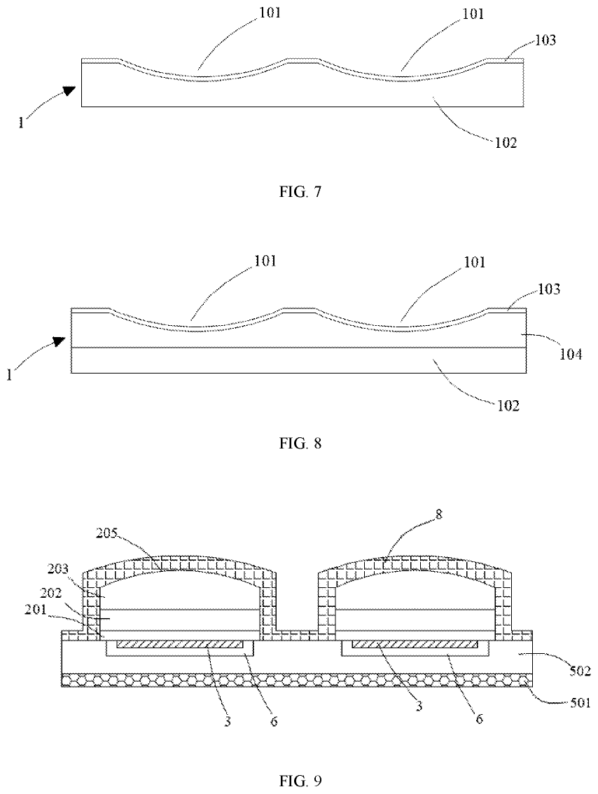

FIG. 7 is a schematic diagram illustrating an epitaxial base according to an embodiment 2 of the present disclosure. The light-emitting device and the method for manufacturing the same of the embodiment 2 of the present disclosure and that of the embodiment 1 of the present disclosure are substantially the same, and the difference lies only in the structure of the epitaxial base. As shown in FIG. 7, the epitaxial base 1 of the embodiment 2 of the present disclosure includes the substrate 102 and the nucleation layer 103 from bottom to top, the first concave portion 101 is formed in the substrate 102, the nucleation layer 103 is formed on the substrate 102 in the same shape with the first concave portion 101. That is, the region of the nucleation layer 103 corresponding to the first concave portion 101 protrudes towards the first concave portion 101 to form a concave structure on a side of the nucleation layer 103 facing away from the substrate 102. The light-emitting structure layer 2 is grown on the side of the nucleation layer 103 facing away from the substrate 102.

### Embodiment 3

FIG. 8 is a schematic diagram illustrating an epitaxial base according to an embodiment 3 of the present disclosure. The light-emitting device and the method for manufacturing the same of the embodiment 3 of the present disclosure and that of the embodiment 1 of the present disclosure are substantially the same, and the difference lies only in the structure of the epitaxial base and a method for removing the epitaxial base. As shown in FIG. 8, the epitaxial base 1 of the embodiment 3 of the present disclosure includes the substrate 102, the dielectric layer 104 and the nucleation layer 103 from bottom to top, the first concave portion 101 is formed in the dielectric layer 104, and the nucleation layer 103 is formed on the dielectric layer 104 in the same shape with the first concave portion 101. The material of the dielectric layer 104 may be SiO₂, etc., but the embodiments of the present disclosure are not specifically limited thereto. The epitaxial base 1 of the embodiment 3 of the present disclosure can be stripped by a chemical etching process. The corrosive solution used for the chemical etching process may be hydrofluoric acid, etc.

### Embodiment 4

FIG. 9 is a schematic diagram illustrating a light-emitting device according to an embodiment 4 of the present disclosure. The light-emitting device and the method for manufacturing the same of the embodiment 4 of the present disclosure and that of any one of the embodiments 1 to 3 of the present disclosure are substantially the same, and the difference lies only in the first reflector layer. As shown in FIG. 9, the first reflector layer 3 of the embodiment 4 of the present disclosure is a metal reflector. The material of the metal reflector may be Ag, Ni/Ag/Ni and so on. Further, in order to avoid oxidation of the first reflector layer 3, the embodiment 4 of the present disclosure can also form a metal protection layer 6 covering the first reflector layer 3. The material of the metal protection layer 6 can be Ni, TiW, Pt, etc. The above-mentioned support layer 5 can wrap the metal protection layer 6.

### Embodiment 5

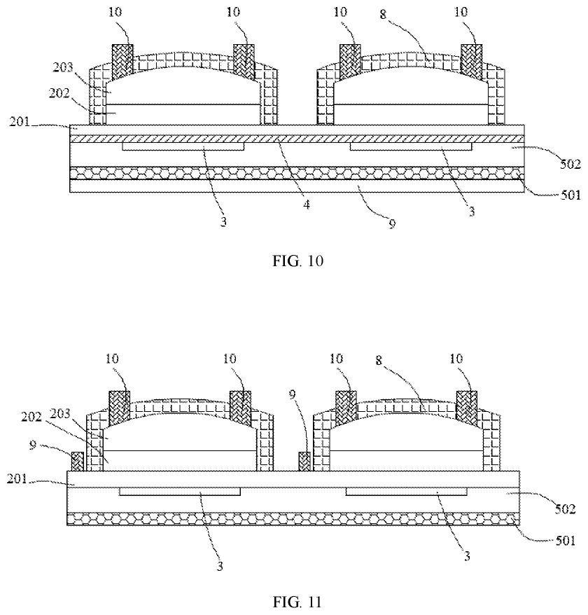

FIG. 10 is a schematic diagram illustrating a light-emitting device according to an embodiment 5 of the present disclosure. The light-emitting device and the method for manufacturing the same of the embodiment 5 of the present disclosure and that of any one of the embodiments 1 to 4 of the present disclosure are substantially the same, and the difference lies only in that: as shown in FIG. 10, a first electrode 9 electrically connected to the first conductive type semiconductor layer 201 and a second electrode 10 electrically connected to the second conductive type semiconductor layer 203 are also formed. The first electrode 9 and the second electrode 10 can be disposed on both sides of the light-emitting structure layer 2. Specifically, the first electrode 9 can be provided on a side of the support layer 5 away from the light-emitting structure layer 2, and the second electrode 10 can be inserted into the second reflector layer 8 and contact with the light-emitting structure layer 2. The light-emitting device of the embodiment 5 of the present disclosure is a light emitting diode (LED) with a resonant cavity. For example, the first conductive type semiconductor layer 201 is a P-type semiconductor layer, the second conductive type semiconductor layer 203 is an N-type semiconductor layer, the first electrode 9 is a P-type electrode, and the second electrode 10 is an N-type electrode. The material of the first electrode 9 and the material of the second electrode 10 may be selected from at least one of gold, silver, aluminum, chromium, nickel, platinum, or titanium.

### Embodiment 6

FIG. 11 is a schematic diagram illustrating a light-emitting device according to an embodiment 6 of the present disclosure. The light-emitting device and the method for manufacturing the same of the embodiment 6 of the present disclosure and that of the embodiment 5 of the present disclosure are substantially the same, and the difference lies only in that: as shown in FIG. 11, both the first electrode 9 and the second electrode 10 are disposed on a side of the first conductive type semiconductor layer 201 away from the first reflector layer 3. Specifically, the first electrode 9 can be disposed on a surface of the first conductive type semiconductor layer 201 facing away from the first reflector layer 3, and the second electrode 10 can be inserted into the second reflector layer 8, and contact with the light-emitting structure layer 2. The light-emitting device the embodiment 6 of the present disclosure is a LED with a resonant cavity, and when the first reflector layer 3 is a distributed Bragg reflector, the ITO layer need not be disposed between the first reflector layer 3 and the first conductive type semiconductor layer 201.

### Embodiment 7

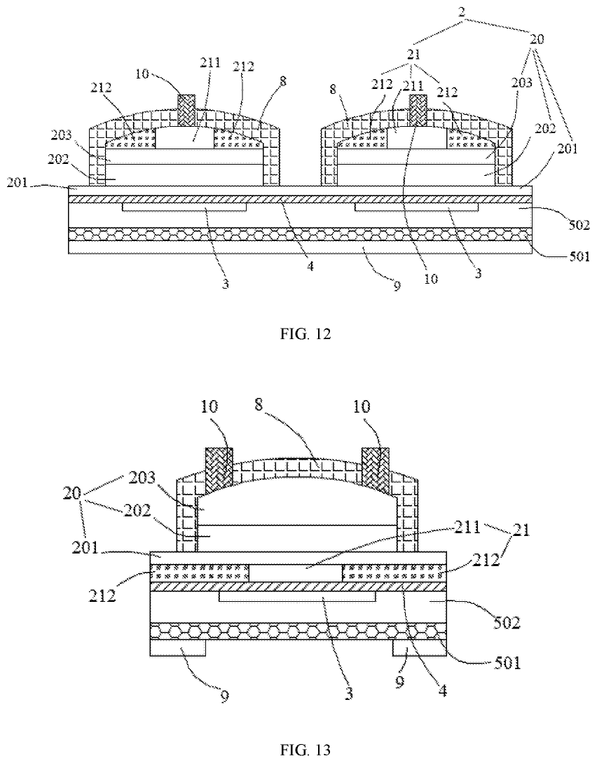

FIG. 12 is a schematic diagram illustrating a light-emitting device according to an embodiment 7 of the present disclosure. FIG. 13 is another schematic diagram illustrating the light-emitting device in the embodiment 7 of the present disclosure. The light-emitting device and the method for manufacturing the same of the embodiment 7 of the present disclosure and that of any one of the embodiments 1 to 5 of the present disclosure are substantially the same, and the difference lies only in the light-emitting structure layer. As shown in FIG. 12 and FIG. 13, the light-emitting structure layer 2 of the embodiment 7 of the present disclosure can include an active layer 20 and an oxide layer 21 stacked. The oxide layer 21 can include a low resistance region 211 and a high resistance region 212. The high resistance region 212 surrounds the low resistance region 211. The low resistance region 211 forms a current aperture (that is, an internal current window), so that the light-emitting device of the embodiment 7 of the present disclosure constitutes a vertical cavity surface emitting laser (VCSEL). The low resistance region 211 also forms an optical pathway of the vertical cavity surface emitting laser.

As shown in FIG. 12 and FIG. 13, the active layer 20 may include the first conductive type semiconductor layer 201, the light-emitting layer 202, and the second conductive type semiconductor layer 203 stacked. As shown in FIG. 12, the oxide layer 21 may also be disposed on a side of the second conductive type semiconductor layer 203 away from the light-emitting layer 202, i.e., the second surface of the light-emitting structure layer 2 is a surface of the oxide layer 21 facing away from the second conductive type semiconductor layer 203. As shown in FIG. 13, the oxide layer 21 can be disposed on a side of the first conductive type semiconductor layer 201 away from the light-emitting layer 202, that is, the first surface of the light-emitting structure layer 2 is a surface of the oxide layer 21 facing away from the first conductive type semiconductor layer 201. Alternatively, the oxide layer 21 may also be disposed in the light-emitting layer 202. The oxide layer 21 can be plural in number. For example, the number of the oxide layer 21 is two, where one oxide layer 21 may be disposed in the light-emitting layer 202 and the other oxide layer 21 may be disposed on a side of the first conductive type semiconductor layer 201 away from the light-emitting layer 202. The oxide layer 21 of the embodiments of the present disclosure can be obtained by oxidizing a monolayer structure of AlInN, AlGaAs, AlAs, or AN, or by oxidizing AlInN/GaN, AlN/GaN, AlGaAs/GaN, or AlAs/GaN.

The above embodiments are some embodiments of the present disclosure, and do not limit the present disclosure in any form. Although the present disclosure has been disclosed as above in the preferred embodiment, it is not intended to limit the present disclosure. Those skilled in the art, without departing from the scope of the technical solutions of the present disclosure, can make some changes or modifications to equivalent embodiments of equivalent changes by using the technical content disclosed above, in the case of where any content does not depart from the technical solutions of the present disclosure, any simple modifications and equivalent changes made to the above embodiments according to the technical essence of the present disclosure still fall within the scope of the technical solutions of the present disclosure.

1. A method for manufacturing a light-emitting device, comprising:
providing an epitaxial base with a first concave portion, wherein an inner surface of the first concave portion is a curved surface;
epitaxially growing a light-emitting structure layer on the epitaxial base, wherein the light-emitting structure layer comprises a first surface and a second surface opposite the first surface, and the second surface protrudes towards the first concave portion;
forming a first reflector layer on the first surface; and
removing the epitaxial base to form a second reflector layer covering the second surface.

2. The method for manufacturing a light-emitting device according to claim 1, wherein the epitaxial base comprises a substrate, and the first concave portion is formed in the substrate.

3. The method for manufacturing a light-emitting device according to claim 1, wherein the epitaxial base comprises a substrate and a nucleation layer from bottom to top, the first concave portion is formed in the substrate, and the nucleation layer is formed on the substrate in a same shape with the first concave portion.

4. The method for manufacturing a light-emitting device according to claim 1, wherein the epitaxial base comprises a substrate, a dielectric layer, and a nucleation layer from bottom to top, the first concave portion is formed in the dielectric layer, and the nucleation layer is formed on the dielectric layer in a same shape with the first concave portion.

5. The method for manufacturing a light-emitting device according to claim 1, wherein the first concave portion is plural in number.

6. The method for manufacturing a light-emitting device according to claim 1, wherein the light-emitting structure layer further comprises a side wall connecting the first surface and the second surface, and forming the second reflector layer covering the second surface comprises:
forming the second reflector layer covering the side wall of the light-emitting structure layer and the second surface.

7. The method for manufacturing a light-emitting device according to claim 1, wherein the second reflector layer has a reflectivity of 50%-80%.

8. The method for manufacturing a light-emitting device according to claim 1, wherein the second reflector layer is made of insulating material.

9. The method for manufacturing a light-emitting device according to claim 1, wherein the light-emitting structure layer further comprises an active layer, which comprises a first conductive type semiconductor layer, a light-emitting layer, and a second conductive type semiconductor layer from top to bottom, and the method further comprising:
forming a first electrode electrically connected to the first conductive type semiconductor layer; and
forming a second electrode electrically connected to the second conductive type semiconductor layer.

10. The method for manufacturing a light-emitting device according to claim 9, wherein the first electrode and the second electrode are respectively disposed on both sides of the light-emitting structure layer.

11. The method for manufacturing a light-emitting device according to claim 9, wherein both the first electrode and the second electrode are disposed on a side of the first conductive type semiconductor layer away from the first reflector layer.

12. The method for manufacturing a light-emitting device according to claim 1, wherein the light-emitting structure layer comprises an active layer and an oxide layer stacked, and the oxide layer comprises a low resistance region and a high resistance region surrounding the low resistance region.

13. A light-emitting device, wherein the light-emitting device is manufactured by the method of claim 1.

14. The method for manufacturing a light-emitting device according to claim 1, wherein area of the first reflector layer is smaller than area of an opening of the first concave portion.

15. The method for manufacturing a light-emitting device according to claim 1, wherein a plurality of first reflector layers corresponds to a plurality of first concave portions one by one.

16. The method for manufacturing a light-emitting device according to claim 1, further comprising: forming an ITO layer on the first surface.

17. The method for manufacturing a light-emitting device according to claim 1, further comprising: forming a support layer wrapping the first reflector layer.

18. The method for manufacturing a light-emitting device according to claim 1, further comprising: forming a metal protection layer covering the first reflector layer.
